(19) United States
(12) Patent Application Publication
(10) Pub. No.: US 2024/0063124 A1
(43) Pub. Date: Feb. 22, 2024

(54) SEMICONDUCTOR DEVICE

(71) Applicant: Socionext Inc., Kanagawa (JP)

(72) Inventor: Sayuri OCHI, Yokohama (JP)

(21) Appl. No.: 18/450,109

(22) Filed: Aug. 15, 2023

(30) Foreign Application Priority Data
Aug. 19, 2022 (JP) 2022-130896

(51) Int. Cl. H01L 23/528; H01L 23/00; H01L 27/088

(52) U.S. Cl. CPC H01L 23/5286; H01L 24/14; H01L 24/13; H01L 27/0886; H01L 2224/13014; H01L 2224/14132

(57) ABSTRACT

A semiconductor device includes first and second power lines; a circuit region including a first region in which first power supply terminals connected to the first power line are arranged at a first density, and a second region in which second power supply terminals connected to the first power line are arranged at a second density lower than the first density; first power switch circuits arranged in the first region and connecting the first and second power lines; and second power switch circuits arranged in the second region and connecting the first and second power lines. A second power supply capability to the second power line by a circuit including the first power line and the second power switch circuits is higher than a first power supply capability to the second power line by a circuit including the first power line and the first power switch circuits.

### CROSS-REFERENCE TO RELATED APPLICATION

The present application is based upon and claims the benefit of priority under 35 U.S.C. § 119 of Japanese Patent Application No. 2022-130896 filed on Aug. 19, 2022, the entire contents of which are hereby incorporated by reference.

### FIELD

The present disclosure relates to a semiconductor device.

### BACKGROUND

There is a conventional technology for achieving low power consumption by providing a power switch circuit to switch on/off the supply of the power supply voltage in a standard cell region of a semiconductor device. There is a conventional technology for reducing the rush current (the inrush current) that causes a drop in the supply source voltage due to the sudden supply of power supply voltage, by providing multiple types of power switch circuits and sequentially turning on the power switch circuits.

### SUMMARY

A semiconductor device according to the present disclosure includes a first power line; a second power line; a circuit region including a first region in which a plurality of first power supply terminals connected to the first power line are arranged at a first density in a planar view, and a second region in which a plurality of second power supply terminals connected to the first power line are arranged at a second density that is lower than the first density in a planar view; a plurality of first power switch circuits arranged in the first region and connecting the first power line to the second power line; and a plurality of second power switch circuits arranged in the second region and connecting the first power line to the second power line, wherein a second power supply capability to the second power line by a circuit including the first power line and the second power switch circuits is higher than a first power supply capability to the second power line by a circuit including the first power line and the first power switch circuits.

The object and advantages of the invention will be implemented and attained by means of the elements and combinations particularly pointed out in the appended claims. It is to be understood that both the foregoing general description and the following detailed description are exemplary and explanatory and are not restrictive of the invention as claimed.

### BRIEF DESCRIPTION OF THE DRAWINGS

FIG. 1 illustrates an example of the layout of a semiconductor device in a first embodiment;

FIG. 2 is a circuit block diagram illustrating an overview of the circuit arranged in a standard cell block of FIG. 1;

FIG. 3 is a planar view illustrating an overview of the layout of the standard cell block of FIG. 1;

FIG. 4 is a planar view illustrating an example of the layout of a power switch circuit PSW of FIG. 2;

FIG. 5 is a cross-sectional view illustrating a cross section along the X1-X1′ line of FIG. 4;

FIG. 6 is a cross-sectional view illustrating a cross section along the Y1-Y1′ line of FIG. 4;

FIG. 7 is a planar view illustrating an example of the layout of the power switch circuit LPSW in FIG. 2;

FIG. 8 is a planar view illustrating an overview of the layout of the standard cell block in the second embodiment;

FIG. 9 is a planar view illustrating an overview of the layout of the standard cell block in the third embodiment;

FIG. 10 is a planar view illustrating an overview of the layout of the standard cell block in the fourth embodiment; and

FIG. 11 is a planar view illustrating an overview of the layout of the standard cell block in the fifth embodiment.

### DESCRIPTION OF EMBODIMENTS

There is a conventional technology for achieving low power consumption by providing a power switch circuit to switch on/off the supply of the power supply voltage in a standard cell region of a semiconductor device. There is a conventional technology for reducing the rush current (the inrush current) that causes a drop in the supply source voltage due to the sudden supply of power supply voltage, by providing multiple types of power switch circuits and sequentially turning on the power switch circuits. (See, for example, Japanese Unexamined Patent Application Publication No. 2011-243794, Japanese Unexamined Patent Application Publication No. 2020-004763, Japanese Unexamined Patent Application Publication No. 2010-283269, U.S. Pat. No. 8,390,331, International Publication No. 2017/208888, Japanese Unexamined Patent Application Publication No. 2010-153535, Japanese Unexamined Patent Application Publication No. 2005-286082, and Japanese Unexamined Patent Application Publication No. 2018-190760)

When multiple power switch circuits are arranged in a large circuit region, if there is a difference in the wiring resistance from the power supply terminal to which the power supply voltage is supplied to the multiple power switch circuits, an IR drop may occur where the resistance is high. Further, in a semiconductor device in which a power supply terminal is provided as a bump, if the wiring resistance from the power supply terminal to the power switch circuits increases in a region where the density of the arrangement of the power supply terminals is low compared to other regions, a difference may arise in the degree of the IR drop. As a result, in regions in which the densities of the arrangement of the power supply terminals are different from each other, a difference arises in the power supply capability to the circuit supplying the power supply voltage.

Accordingly, it is desired to prevent a difference from arising in the power supply capability to the circuit supplying the power supply voltage in regions in which the arrangement densities of the power supply terminals are different from each other.

Embodiments will be described below with reference to drawings. In the following, the symbol indicating the signal is also used as the symbol indicating the signal value, the signal line, or the signal terminal. The symbol indicating the power supply voltage is also used as the symbol indicating the power supply line or the terminal to which the power supply voltage is supplied.

### First Embodiment

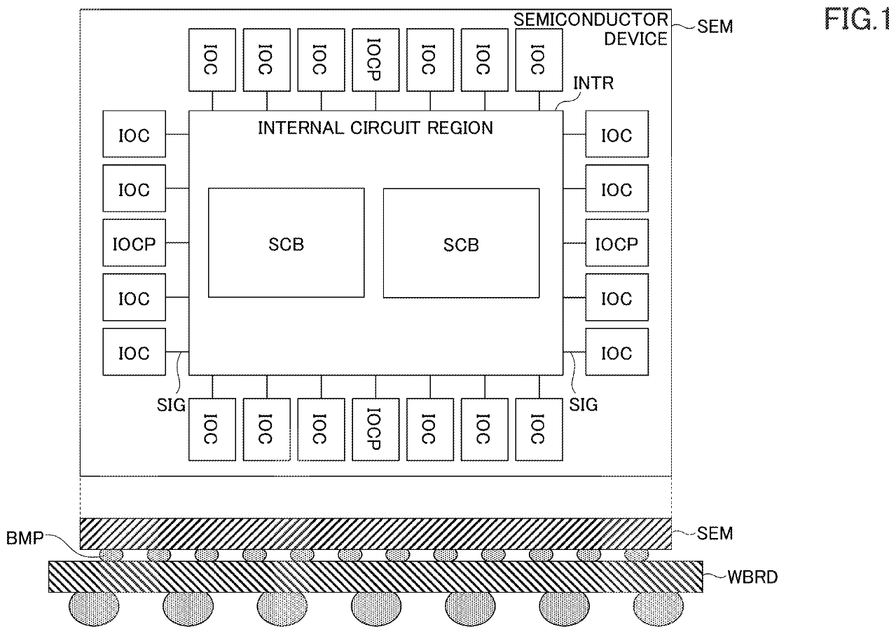

FIG. 1 illustrates an example of the layout of a semiconductor device in the first embodiment. For example, the semiconductor device SEM illustrated in FIG. 1 may be a SoC (System on a Chip), a single FPGA (Field-Programmable Gate Array), an ASIC (Application Specific Integrated Circuit), or the like.

The semiconductor device SEM has multiple I/O cells IOC, IOCP, each connected to a bump BMP. The I/O cell IOC is an interface circuit for a signal SIG such as an input signal, an output signal, or an input/output signal. The I/O cell IOCP is an interface circuit for a power supply voltage or a ground voltage.

Each I/O cell IOC, IOCP is connected to an internal circuit region INTR. For example, the internal circuit region INTR has a plurality of standard cell blocks SCB in which standard cells are provided. The internal circuit region INTR may have logic circuits other than the standard cells or a memory installed therein. The number and ratio of I/O cells IOC and I/O cells IOCP are not limited to the example illustrated in FIG. 1.

The semiconductor device SEM is connected to a pad (not illustrated) on the surface of the wiring board WBRD through, for example, a plurality of bumps BMP provided on the surface of the semiconductor device SEM. An external connection terminal (for example, a bump) is provided on the back of the wiring board WBRD.

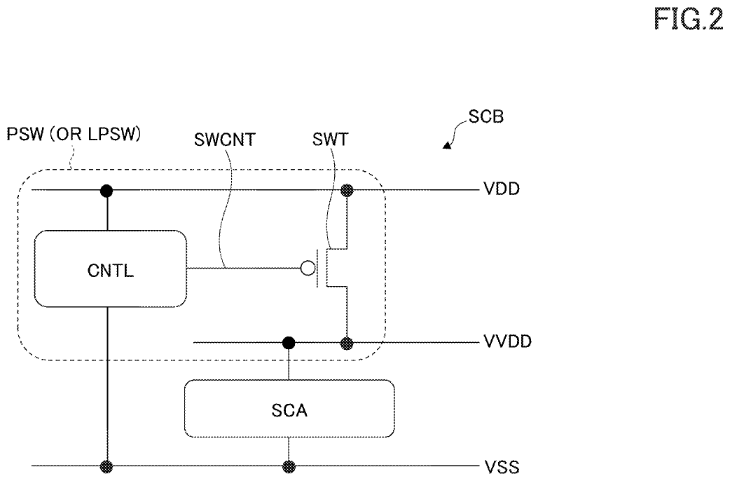

FIG. 2 is a circuit block diagram illustrating the outline of the circuit arranged in the standard cell block SCB of FIG. 1. The standard cell block SCB includes a power switch circuit PSW (or a power switch circuit LPSW) and a standard cell region SCA. The standard cell region SCA is electrically connected to a virtual power line VVDD and a ground line VSS, and operates by receiving a power supply voltage from the virtual power line VVDD.

The power switch circuit PSW (or the power switch circuit LPSW) includes a switch transistor SWT and a control circuit CNTL. The power switch circuit LPSW has the same configuration as the power switch circuit PSW except that the size of the switch transistor SWT is larger and the power supply capability is higher than that of the power switch circuit PSW.

The power switch circuit PSW is an example of a first power switch circuit. The power switch circuit LPSW is an example of a second power switch circuit. The switch transistor SWT of the power switch circuit PSW is an example of a first switch transistor. The switch transistor SWT of the power switch circuit LPSW is an example of a second switch transistor.

The switch transistor SWT is, for example, a p-channel transistor whose source is connected to the power line VSS and whose drain is connected to the virtual power line VVDD, and operates by receiving a switch control signal SWCNT from the control circuit CNTL at the gate thereof. Although one switch transistor SWT is illustrated in FIG. 2 for simplicity, multiple switch transistors SWT may be arranged between the power line VDD and the virtual power line VVDD. The power line VDD is an example of the first power line, and the virtual power line VVDD is an example of the second power line.

While the switch transistor SWT is on, the power line VDD and the virtual power line VVDD are electrically connected, and the power supply voltage VDD is supplied to the virtual power line VVDD. While the switch transistor SWT is off, the electrical connection between the power line VDD and the virtual power line VVDD is cut off, and the virtual power line VVDD is set to a floating state.

The control circuit CNTL is, for example, a buffer circuit. When operating a circuit in the standard cell region SCA, the control circuit CNTL sets the switch control signal SWCNT to a low level and supplies a power supply voltage from the power supply line VDD to the virtual power supply line VVDD. When stopping the operation of a circuit in the standard cell region SCA, the control circuit CNTL sets the switch control signal SWCNT to a high level and stops the supply of a power supply voltage from the power supply line VDD to the virtual power supply line VVDD.

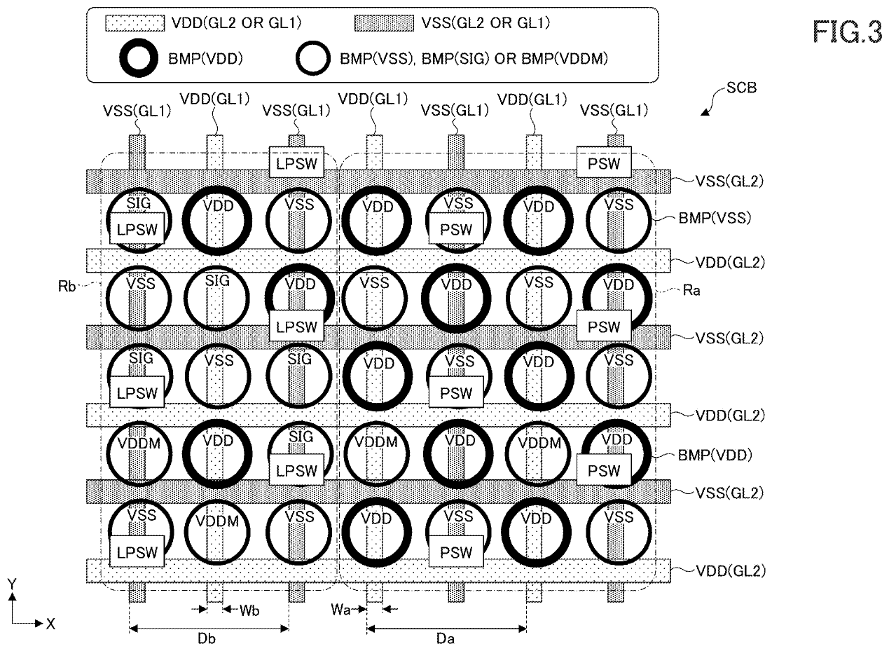

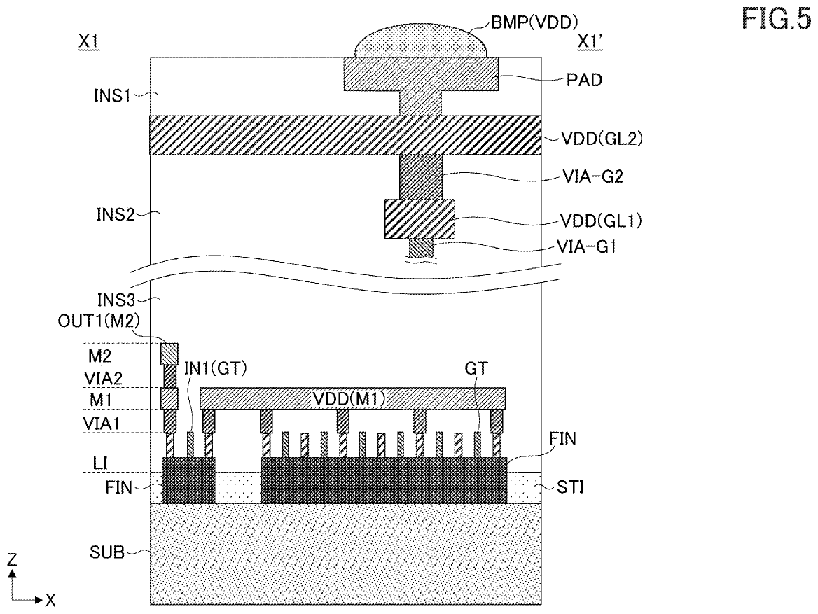

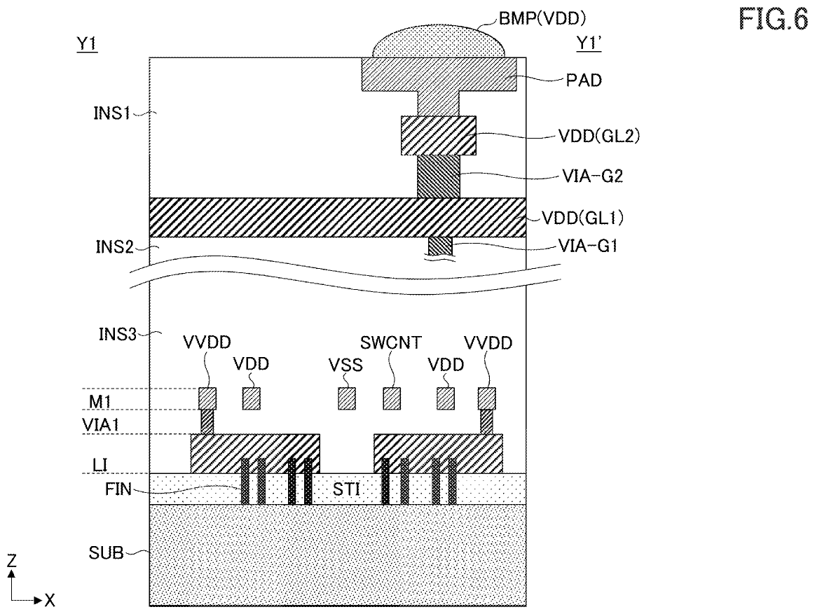

FIG. 3 is a planar view illustrating an overview of the layout of the standard cell block SCB of FIG. 1. In FIG. 3, a part of the region of the standard cell block SCB is illustrated as viewed (planar view) from the surface of the semiconductor device SEM (the surface on which the bumps BMP are formed). In FIG. 3, each bump BMP is illustrated in a ring shape to make it easier to see the wiring hidden by the bump BMP. For simplicity of explanation, the size of each bump BMP is smaller than the actual size. An image of the actual size of the bump BMP is illustrated in FIGS. 5 and 6.

A power line VDD (GL2) and a ground line VSS (GL2) are provided along the X direction in FIG. 3 by using a global wiring layer GL2 closest to the bump BMP. A power line VDD (GL1) and a ground line VSS (GL1) are provided along the Y direction in FIG. 3 by using a global wiring layer GL1 located on the opposite side of the bump BMP with respect to the global wiring layer GL2. The global wiring layers GL2 and GL1 are provided on the surface side of the semiconductor device SEM.

The power line VDD (GL2) and the power line VDD (GL1) are connected to each other through a via that is not illustrated. The ground line VSS (GL2) and the ground line VSS (GL1) are connected to each other through a via that is not illustrated. For simplicity of explanation, the illustration of the signal line SIG and the power line VDDM, which are provided by using the global wiring layers GL2 and GL1, is omitted. The bump BMP (VDDM) and the power line VDDM are used to supply power voltage to the memory when the memory is provided in the standard cell block SCB.

The widths Wa, Wb of the power line VDD (GL1) or the ground line VSS (GL1) arranged in the regions Ra, Rb in FIG. 3 are equal to each other. Also, the arrangement pitches Pa, Pb of the power line VDD (GL1) or the ground line VSS (GL1) arranged in the regions Ra, Rb are equal to each other. The region Ra is an example of the first region and the region Rb is an example of the second region. Although not particularly limited, in FIG. 3, six power switch circuits PSW are arranged in the region Ra and six power switch circuits LPSW are arranged in the region Rb.

For example, the power switch circuits PSW and LPSW, which are provided by using the semiconductor and wiring layers on the back side of the semiconductor device SEM (on the side opposite to the front side where the bumps BMP are arranged), are placed at the very front in FIG. 3 for ease of viewing.

For example, the size of the switch transistor SWT (FIG. 2) of the power switch circuit LPSW is set to 2.5 times the size of the switch transistor SWT of the power switch circuit PSW. Here, the size of the switch transistor SWT indicates the power supply capability of each power switch circuit LPSW, PSW to the virtual power supply line VVDD when the arrangement density of the bumps BMP (VDD) and the wiring resistance of the power supply line VDD are not considered. For example, if the switch transistor SWT is a FinFET (Fin Field Effect Transistor), the size of the switch transistor SWT and the power supply capability of each power switch circuit LPSW, PSW alone to the virtual power supply line VVDD are expressed by the product of the number of gates and the number of fins.

In the region Ra, 20 bumps BMP are arranged, including 10 bumps BMP (VDD) in planar view. In the region Rb, 15 bumps BMP are arranged, including 3 bumps BMP (VDD) in planar view. Therefore, the arrangement density (3/15=0.2) of bumps BMP (VDD) in the region Rb is 40% of the arrangement density (10/20=0.5) of bumps BMP (VDD) in the region Ra.

The bump BMP (VDD) arranged in the region Ra is an example of a first power supply terminal. The bump BMP (VDD) arranged in the region Rb is an example of a second power supply terminal. The arrangement density of the bumps BMP (VDD) in the region Ra is an example of the first density. The arrangement density of the bumps BMP (VDD) in the region Rb is an example of the second density.

In the present embodiment, for example, the product of the arrangement density of the bumps BMP (VDD) and the size of the switch transistor SWT is set to be equal in the regions Ra and Rb. Therefore, even when the arrangement density of the bumps BMP (VDD) is lower than that in the region Ra, the actual power supply capability to the virtual power supply line VVDD in the region Rb can be greater than or equal to the actual power supply capability to the virtual power supply line VVDD in the region Ra.

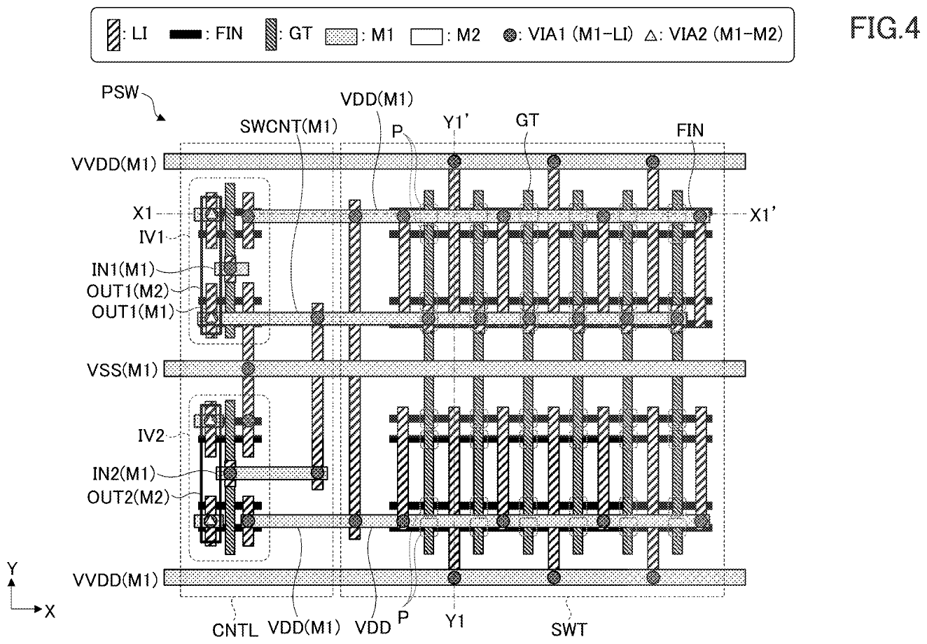

FIG. 4 is a planar view illustrating an example of the layout of the power switch circuit PSW in FIG. 2. In the legend illustrated in FIG. 4, the symbol LI indicates the local wiring and the symbol FIN indicates the fin. The symbol GT indicates the gate of the switch transistor SWT. The symbol M1 indicates the first wiring layer and the symbol M2 indicates the second wiring layer. The symbol VIA1 indicates a via connecting the wiring layer M1 and the local wiring LI.

The power switch circuit PSW includes the switch transistor SWT and the control circuit CNTL illustrated in FIG. 2. The control circuit CNTL includes inverters IV1 and IV2 connected to the power supply line VDD (M1) and the ground line VSS (M1). The inverters IV1 and IV2 are connected in series and operate as buffers. The inverter IV1 inverts the level of the signal received at the input terminal IN1 and outputs the signal, as the switch control signal SWCNT, to the switch control signal line SWCNT connected to the output terminal OUT1.

The switch control signal SWCNT is supplied to the gate GT of the p-channel transistor P provided in the switch transistor SWT and the input terminal IN2 of the inverter IV2. The p-channel transistor P is indicated by a dashed line rectangular frame with arc-shaped corners. By the switch control signal SWCNT, the on and off of the p-channel transistor P of the switch transistor SWT is controlled, and the supply of the power supply voltage from the power supply line VDD to the virtual power supply line VVDD is controlled. The switch transistor SWT illustrated in FIG. 4 includes 48 p-channel transistors P provided at the intersections of six gates GT and eight fins FIN. The p-channel transistor P provided in the power switch circuit PSW is an example of the first transistor.

The inverter IV2 inverts the level of the switch control signal SWCNT received at the input terminal IN2 and outputs the signal from the output terminal OUT2. For example, the signal output from the output terminal OUT2 may be supplied to the input terminal IN1 of the control circuit CNTL of another power switch circuit PSW (not illustrated) arranged adjacent in the Y direction to the power switch circuit PSW illustrated in FIG. 4.

Each of the multiple p-channel transistors P has a source electrically connected to the power line VDD (M1), a drain electrically connected to the virtual power line VVDD (M1), and a gate GT electrically connected to the switch control signal line SWCNT (M1). Here, the source of the p-channel transistor P is provided on one of the fins FIN facing each other across the gate. The drain of the p-channel transistor P is provided on the other one of the fins FIN facing the source across the gate.

One of the fins FIN is connected to the power supply line VDD (M1) via the local wiring LI and the other one of the fins FIN is connected to the virtual power supply line VVDD (M1) via the local wiring LI. The virtual power supply line VVDD (M1) connected to the switch transistor SWT extends along the X-direction and is connected to the standard cell region SCA.

FIG. 5 is a cross-sectional view illustrating a cross section along the X1-X1′ line of FIG. 4. The bump BMP (VDD) provided on the surface side of the semiconductor device SEM is connected to the power line VDD (GL2) through a pad PAD provided by opening the insulating film INS1. The power line VDD (GL2) is connected to the power line VDD (GL1) through a via VIA-G2.

The power line VDD (GL1) is connected to the power line VDD (M1) provided on the back side of the semiconductor device SEM through a via VIA-G1 provided by opening the insulating film INS2 and a TSV and the like (not illustrated) provided on the insulating film INS3. The power line VDD (M1) is then connected to the source of the p-channel transistor P provided in the fin FIN. That is, the bump BMP (VDD) is electrically connected to the source of the p-channel transistor P (FIG. 4) via the power line VDD in each layer. On the surface of the semiconductor substrate SUB, an STI (Shallow Trench Isolation) film is formed as an insulating film.

FIG. 6 is a cross-sectional view illustrating a cross section along the line Y1-Y1′ in FIG. 4. Elements similar to those in FIG. 5 are denoted by the same symbols and detailed descriptions are omitted. The wiring structure from the bump BMP (VDD) to the via VIA-G1 is similar to that in FIG. 5. The virtual power line VVDD (M1) is connected to the local wiring LI through the via VIA1 and further to the fin FIN provided in the switch transistor SWT. The fin FIN is provided on the semiconductor substrate SUB. The gate insulation film formed between the gate GT and the fin FIN is not illustrated.

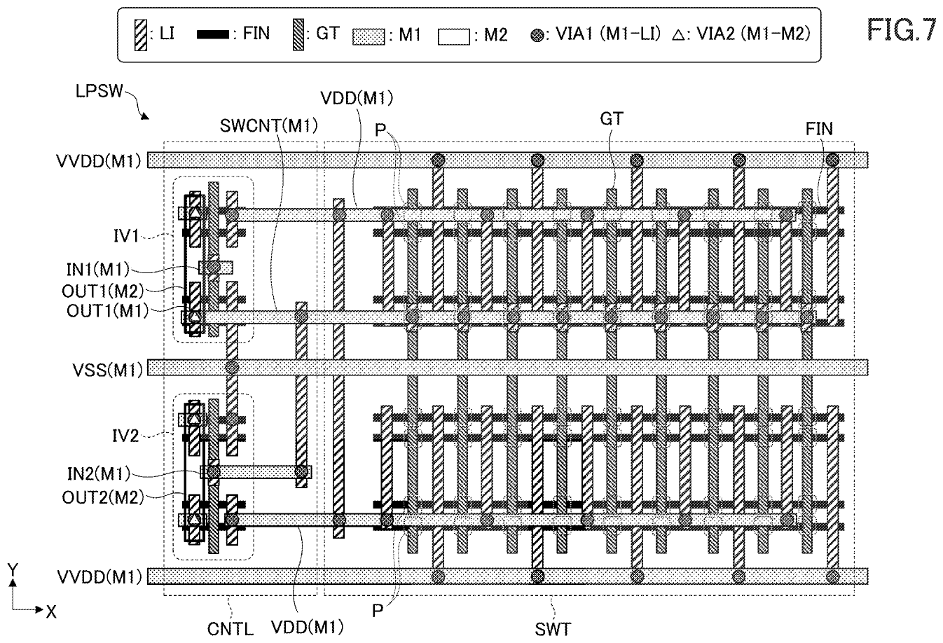

FIG. 7 is a planar view illustrating an example of the layout of the power switch circuit LPSW in FIG. 2. Elements similar to the power switch circuit PSW illustrated in FIG. 4 are denoted by the same symbols and detailed descriptions are omitted.

The power switch circuit LPSW has the same configuration as the power switch circuit PSW illustrated in FIG. 4 except that the number of gates GT is nine. That is, the number of gates GT in the power switch circuit LPSW is 1.5 times the number (six) of gates GT in the power switch circuit PSW. That is, the size of the switch transistor SWT of one power switch circuit LPSW is approximately 1.5 times the size of the switch transistor SWT of one power switch circuit PSW. The switch transistor SWT illustrated in FIG. 7 has 72 p-channel transistors P provided at the intersections of nine gates GT and eight fins FIN. The p-channel transistor P provided in the power switch circuit LPSW is an example of the second transistor.

Therefore, when the wiring resistances of the power supply lines VDD are the same as each other, the power supply capability of the power switch circuit LPSW alone to the virtual power supply line VVDD can be increased to approximately 1.5 times the power supply capability of the power switch circuit PSW alone to the virtual power supply line VVDD. Thus, even when the arrangement density of the bumps BMP (VDD) is low, the rise in the wiring resistance of the power supply line can be prevented to reduce the IR drop of the power supply voltage VDD, and the decline in the power supply capability to the virtual power supply line VVDD can be prevented. As a result, the actual power supply capability to the virtual power supply line VVDD in the region Rb where the arrangement density of the bumps BMP (VDD) is low compared to the region Ra, can be made equivalent to the actual power supply capability to the virtual power supply line VVDD in the region Ra.

Note that, in the present embodiment and embodiments described later, the conditions for making the power supply capability to the virtual power supply line VVDD in the region Rb equivalent to the power supply capability to the virtual power supply line VVDD in the region Ra, can be determined by formula (1). However, the threshold voltages of the p-channel transistors P of the power switch circuits PSW and LPSW are made equal to each other. The widths of the power lines VDD (GL2) in the regions Ra and Rb are made equal to each other, and the arrangement densities of the power lines VDD (GL2) in the regions Ra and Rb are made equal to each other.

Ba×(Ga×Fa×Pa×Wa×Da)=Bb×(Gb×Fb×Pb×Wb×Db) (1)

The meanings of the symbols indicated in formula (1) are as follows.
Ba: Arrangement density of bumps BMP (VDD) in the region Ra
Ga: Number of gates GT in each switch transistor SWT in the region Ra
Fa: Number of fins FIN in each switch transistor SWT in the region Ra
Pa: Number of power switch circuits PSW in the region Ra (arrangement density)
Wa: Width of each power line VDD (GL1) in the region Ra
Da: Arrangement pitch (arrangement density) of power lines VDD (GL1) in the region Ra
Bb: Arrangement density of bumps BMP (VDD) in the region Rb
Gb: Number of gates GT in each switch transistor SWT in the region Rb
Fb: Number of fins FIN of each switch transistor SWT in the region Rb
Pb: Number of power switch circuits PSW in the region Rb (arrangement density)
Wb: Width of each power line VDD (GL1) in the region Rb
Db: Arrangement pitch (arrangement density) of power lines VDD (GL1) in the region Rb

In formula (1), “Ga×Fa×Pa×Wa×Da” indicates the power supply capability (the power supply capability of a circuit alone including the power line VDD and the power switch circuit PSW) to the virtual power line VVDD in the region Ra when the arrangement density of the bump BMP (VDD) is not considered. In formula (1), “Gb×Fb×Pb×Wb×Db” indicates the power supply capability (the power supply capability of a circuit alone including the power line VDD and the power switch circuit LPSW) to the virtual power line VVDD in the region Rb when the arrangement density of the bumps BMP (VDD) is not considered. The power supply capability of a circuit alone to the virtual power line VVDD in the region Ra is an example of the first power supply capability. The power supply capability of a circuit alone to the virtual power line VVDD in the region Rb is an example of the second power supply capability.

In the present embodiment, “number Fa of fins FIN”=“number Fb of fins FIN” and “number Pa of power switch circuits PSW”=“number Pb of power switch circuits LPSW”. Also, “width Wa of each power supply line VDD (GL1)”=“width Wb of each power supply line VDD (GL1)” and “arrangement pitch Da of power supply line VDD (GL1)”=“arrangement pitch Db of power supply line VDD (GL1)”. Thus, formula (1) can be transformed into formula (2).

Ba×Ga=Bb×Gb (2)

In formula (2), “Ga” indicates the power supply capability to the virtual power line VVDD by the circuit alone without considering the arrangement density of the bumps BMP (VDD) in the region Ra. In formula (2), “Gb” indicates the power supply capability to the virtual power line VVDD by the circuit alone without considering the arrangement density of the bumps BMP (VDD) in the region Rb. In formula (2), “Ba×Ga” on the left side indicates the actual power supply capability to the virtual power line VVDD, expressed by the product of the arrangement density of the bumps BMP (VDD) and the power supply capability by the circuit alone in the region Ra. In formula (2), “Bb×Gb” on the right side indicates the actual power supply capability to the virtual power line VVDD, expressed by the product of the arrangement density of the bumps BMP (VDD) and the power supply capability in the region Rb. “Ba×Ga” is an example of the first parameter. “Bb×Gb” is an example of the second parameter.

The arrangement densities Ba and Bb of the bumps BMP (VDD) are “0.5” and “0.2”, respectively, as explained with reference to FIG. 3. The numbers Ga and Gb of the gates GT are six and nine, respectively. In this case, the left side of formula (2) becomes “3” and the right side of formula (2) becomes “1.8”.

Therefore, the actual power supply capability to the virtual power line VVDD in the region Rb is insufficient with respect to the actual power supply capability to the virtual power line VVDD in the region Ra. For example, by setting the number Gb of the gates GT in the switch transistor SWT of each power switch circuit LPSW to 15, the right side of formula (2) can be set to “3”, and can be made equal to the left side of formula (2).

The threshold voltage of the p-channel transistor P of the power switch circuit LPSW may be set lower than the threshold voltage of the p-channel transistor P of the power switch circuit PSW. In this case, for example, even if the number Gb of the gates GT of the power switch circuit LPSW is nine, the actual power supply capability to the virtual power supply line VVDD in the region Rb can be greater than or equal to the actual power supply capability to the virtual power supply line VVDD in the region Ra.

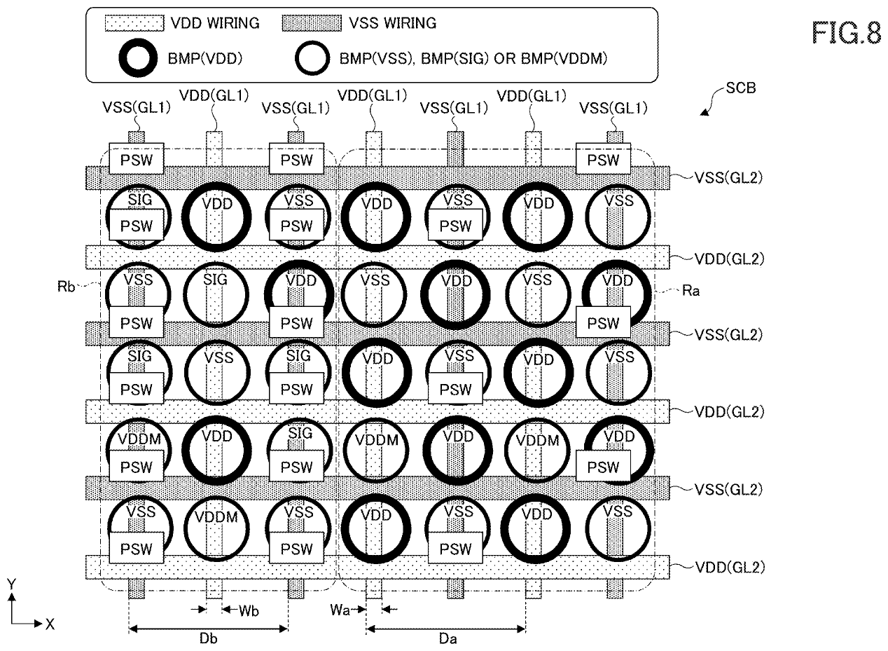

In one or more of the second to fifth embodiments (FIGS. 8, 9, 10 and 11) described later, the power switch circuit LPSW may be arranged instead of the power switch circuit PSW in the region Rb.

As described above, in the present embodiment, the power switch circuit LPSW, which has higher power supply capability than the power switch circuit PSW, is arranged in the region Rb, where the arrangement density of the bumps BMP (VDD) is lower than that in the region Ra. Therefore, in the region Rb, the rise in the wiring resistance of the power line VDD, which is provided between the bump BMP (VDD) and the power switch circuit LPSW, can be prevented, and the IR drop of the power supply voltage VDD can be reduced.

As a result, the decline in the actual power supply capability to the virtual power line VVDD in the region Rb can be prevented, and the actual power supply capability to the virtual power line VVDD in the region Rb can be made greater than or equal to the actual power supply capability to the virtual power line VVDD in the region Ra. That is, it is possible to prevent a difference from arising in the power supply capability to supply the virtual power line VVDD with power to the circuit in the standard cell region SCA, between the regions Ra and Rb where the arrangement density of the bumps BMP (VDD) is different from each other.

### Second Embodiment

FIG. 8 is a planar view illustrating the outline of the layout of the standard cell block SCB in the second embodiment. Elements similar to those in the standard cell block SCB illustrated in FIG. 3 are denoted by the same symbols and detailed descriptions are omitted. As in FIG. 1, the standard cell block SCB illustrated in FIG. 8 is provided in the internal circuit region INTR of the semiconductor device SEM and has the same circuit configuration as in FIG. 2.

In the present embodiment, the arrangement densities Ba and Bb of the bumps BMP (VDD) are “0.5” and “0.2”, respectively, as in FIG. 3. Also, in FIG. 8, a plurality of power switch circuits PSW are arranged in the region Rb instead of the plurality of power switch circuits LPSW in FIG. 3. That is, power switch circuits PSW having the same circuit configuration are arranged in the regions Ra and Rb.

Other configurations of the standard cell block SCB are the same as those in FIG. 3. For example, the number Pb of power switch circuits PSW arranged in the region Rb is twice the number Pa of power switch circuits PSW arranged in the region Ra. That is, the arrangement density Pb of power switch circuits PSW arranged in the region Rb is twice the arrangement density Pb of power switch circuits PSW arranged in the region Ra. The power switch circuits PSW may be stacked and arranged in the semiconductor device SEM.

Accordingly, as in the first embodiment, the rise in the wiring resistance of the power line VDD provided between the bump BMP (VDD) and the power switch circuit PSW in the region Rb can be prevented, thereby reducing the IR drop of the power voltage VDD. As a result, the decline in the actual power supply capability to the virtual power line VVDD in the region Rb can be prevented, and the actual power supply capability to the virtual power line VVDD in the region Rb can be made greater than or equal to the actual power supply capability to the virtual power line VVDD in the region Ra.

Also in the present embodiment, the condition that makes the actual power supply capability to the virtual power line VVDD in the region Rb equivalent to the actual power supply capability to the virtual power line VVDD in the region Ra, can be determined by the above formula (1). In formula (1), the elements other than the arrangement densities Ba and Bb of the bumps BMP (VDD) and the numbers Pa and Pb of the power switch circuits PSW, are the same on the left and right sides, and, therefore, formula (1) can be transformed into formula (3).

Ba×Pa=Bb×Pb (3)

In formula (3), “Pa” indicates the power supply capability to the virtual power line VVDD by the circuit alone without considering the arrangement density of the bumps BMP (VDD) in the region Ra. In formula (3), “Pb” indicates the power supply capability to the virtual power line VVDD by the circuit alone without considering the arrangement density of the bumps BMP (VDD) in the region Rb.

In formula (3), “Ba×Pa” on the left side indicates the actual power supply capability to the virtual power line VVDD in the region Ra, expressed by the product of the arrangement density of the bumps BMP (VDD) and the power supply capability. In formula (1), “Bb×Pb” on the right side indicates the actual power supply capability to the virtual power line VVDD in the region Rb, expressed by the product of the arrangement density of the bumps BMP (VDD) and the power supply capability. In formula (3), “Ba×Pa” on the left side is an example of the first parameter. In formula (3), “Bb×Pb” on the right side is an example of the second parameter.

The arrangement densities Ba and Bb of the bumps BMP (VDD) are “0.5” and “0.2”, respectively, as explained with reference to FIG. 3. Moreover, the numbers Pa and Pb of the power switch circuit PSW are “8” and “12”, respectively. In this case, the left side of formula (3) becomes “4” and the right side of formula (3) becomes “2.4”.

Therefore, the power supply capability to the virtual power line VVDD with the power switch circuit PSW alone in the region Rb is insufficient with respect to the power supply capability to the virtual power line VVDD with the power switch circuit PSW alone in the region Ra. Here, the power supply capability with the power switch circuit PSW alone is the power supply capability to the virtual power line VVDD with the power switch circuit PSW alone without considering the arrangement density of the bumps BMP (VDD) and the wiring resistance of the power line VDD.

However, for example, by setting the number Pb of the power switch circuits PSW provided in the region Rb to 20, the right side of formula (3) can be set to “4” and can be made equal to the left side of formula (3).

The threshold voltage of the p-channel transistor P of the power switch circuit LPSW may be set lower than the threshold voltage of the p-channel transistor P of the power switch circuit PSW. In this case, for example, even if the number Pb of power switch circuits PSW provided in the region Rb is 12, the product of the arrangement density of bumps BMP (VDD) and the power supply capability of the circuit alone including the power line VDD and the power switch circuit PSW can be made equal to each other in the regions Ra and Rb.

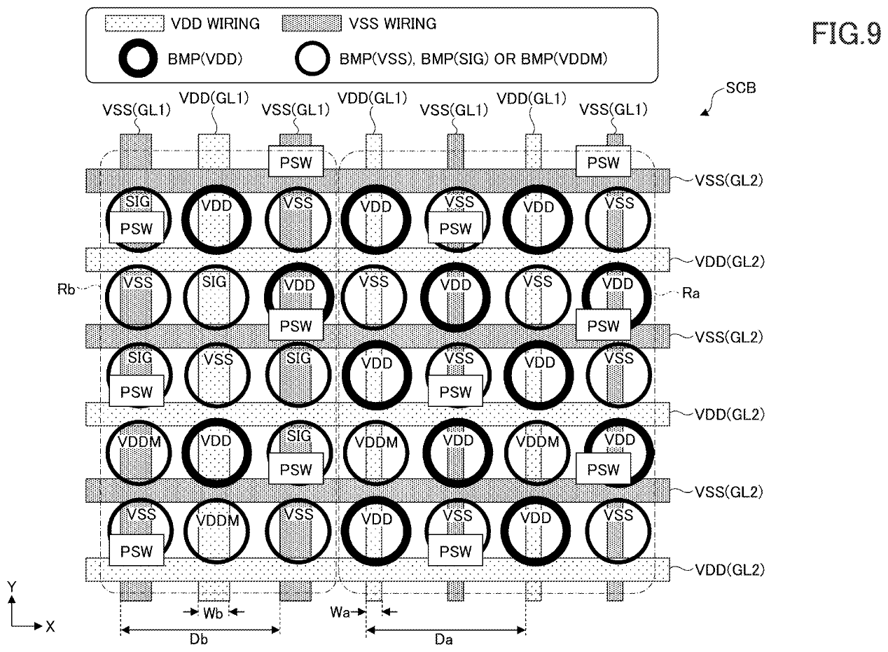

Also, in one or more of the first embodiment (FIG. 3) and the third to fifth embodiment (FIGS. 9, 10, and 11) described later, the number Pb of power switch circuits PSW (or LPSW) in the region Rb may be larger than the number Pa of power switch circuits PSW in the region Ra.

As described above, the same effect as the first embodiment can be obtained in the present embodiment. For example, the arrangement density of the power switches PSW in the region Rb, where the arrangement density Bb of the bumps BMP (VDD) is lower than that in the region Ra, can be made higher than the arrangement density of the power switch circuits PSW in the region Ra.

Thus, by using the existing power switch circuit PSW, a rise in the wiring resistance of the power line VDD provided between the bump BMP (VDD) and the power switch circuit LPSW in the region Rb can be prevented, and the IR drop of the power supply voltage VDD can be reduced. As a result, even when the arrangement density Bb of the bumps BMP (VDD) in the region Rb is relatively low, the actual power supply capability to the virtual power line VVDD in the region Rb can be made greater than or equal to the actual power supply capability to the virtual power line VVDD in the region Ra.

### Third Embodiment

FIG. 9 is a planar view illustrating the outline of the layout of the standard cell block SCB in the third embodiment. Elements similar to those of the standard cell block SCB illustrated in FIG. 3 are denoted by the same symbols and detailed descriptions are omitted. The standard cell block SCB illustrated in FIG. 9 is provided in the internal circuit region INTR of the semiconductor device SEM as in FIG. 1, and has the same circuit configuration as in FIG. 2.

In the present embodiment, the arrangement densities Ba and Bb of the bumps BMP (VDD) are “0.5” and “0.2”, respectively, as in FIG. 3. Further, the widths Wb of the power supply line VDD (GL1) and the ground line VSS (GL1) provided in the region Rb are set to be thicker than the widths Wa of the power supply line VDD (GL1) and the ground line VSS (GL1) provided in the region Ra. The power supply lines VDD (GL1) may be provided by being stacked in the semiconductor device SEM.

In the region Rb, the multiple power supply switch circuits PSW are arranged instead of the multiple power supply switch circuits LPSW in FIG. 3. The number of power supply switch circuits PSW arranged in the region Rb is equal to the number of power supply switch circuits PSW arranged in the region Ra. That is, the numbers of gates GT in each switch transistor SWT in the regions Rb, Ra are equal to each other, and the numbers of fins FIN in each switch transistor SWT in the regions Rb, Ra are equal to each other.

Further, the arrangement densities (arrangement pitches) Db and Da of the power supply lines VDD (GL1) and the ground lines VSS (GL1) in the regions Rb and Ra are equal to each other. The other configurations of the standard cell block SCB are the same as those in FIG. 3.

Also in the present embodiment, the condition that makes the actual power supply capability to the virtual power line VVDD in the region Rb equal to the actual power supply capability to the virtual power line VVDD in the region Ra can be determined by the above formula (1). In formula (1), each element other than the arrangement densities Ba and Bb of the bumps BMP (VDD) and the widths Wa and Wb of each power line VDD (GL1) are the same on the left and right sides, and, therefore, formula (1) can be transformed into formula (4).

Ba×Wa=Bb×Wb (4)

In formula (4), “Wa” indicates the power supply capability to the virtual power line VVDD by the circuit alone without considering the arrangement density of the bumps BMP (VDD) in the region Ra. In formula (4), “Wb” indicates the power supply capability to the virtual power line VVDD by the circuit alone without considering the arrangement density of the bumps BMP (VDD) in the region Rb.

The left side of formula (4), “Ba×Wa”, indicates the actual power supply capability to the virtual power line VVDD, which is expressed by the product of the arrangement density of the bumps BMP (VDD) and the power supply capability, in the region Ra. The right side of formula (4), “Bb×Wb”, indicates the actual power supply capability to the virtual power line VVDD, which is expressed by the product of the arrangement density of the bumps BMP (VDD) and the power supply capability, in the region Rb. The left side of formula (4), “Ba×Wa”, is an example of the first parameter. The right side of formula (4), “Bb×Wb”, is an example of the second parameter.

In the present embodiment, by making the width Wb of each power supply line VDD (GL1) in the region Rb thicker than the width Wa of each power supply line VDD (GL1) in the region Ra, the actual power supply capability to the virtual power supply line VVDD can be made equal in the regions Rb and Ra. The threshold voltage of the p-channel transistor P of the power switch circuit PSW in the region Rb may be set lower than the threshold voltage of the p-channel transistor P of the power switch circuit PSW in the region Rb.

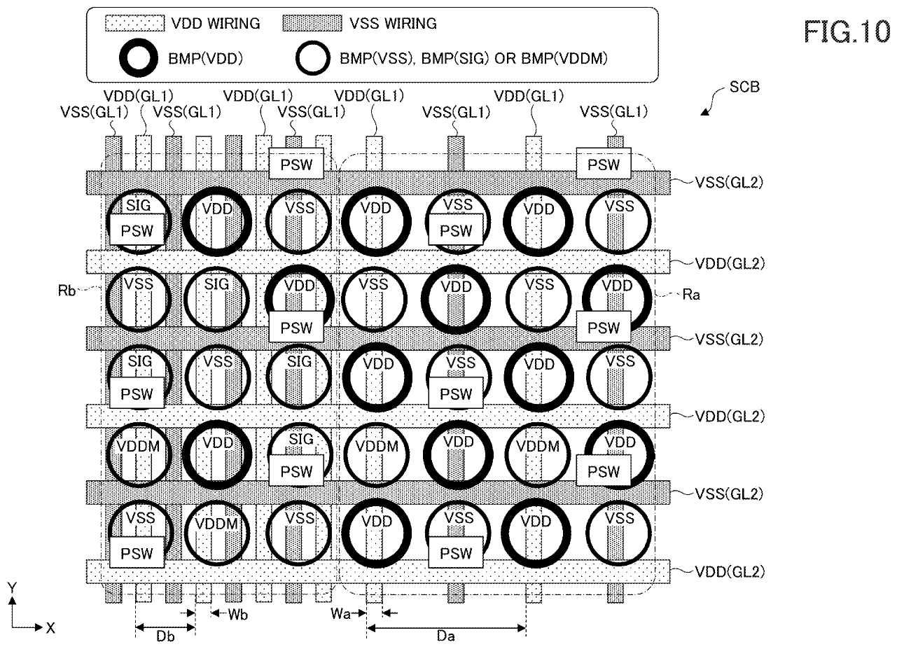

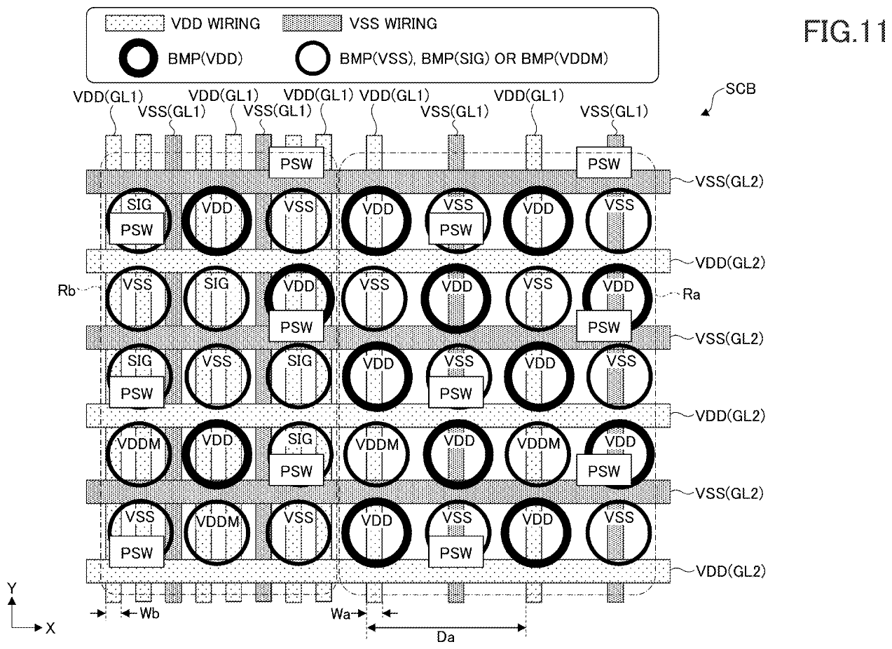

In one or more of the first embodiment (FIG. 3), the second embodiment (FIG. 8), the fourth embodiment (FIG. 10), and the fifth embodiment (FIG. 11), the width Wb of the power line VDD (GL1) in the region Rb may be thicker than the width Wa of the power line VDD (GL1) in the region Ra. When the regions Ra and Rb are arranged side by side in the Y direction, the width of the power line VDD (GL2) provided in the region Rb may be thicker than the width of the power line VDD (GL2) provided in the region Ra.

As described above, the same effect as the above described embodiment can be obtained in the present embodiment. For example, the width Wb of each power supply line VDD (GL1) in the region Rb, where the arrangement density Bb of the bumps BMP (VDD) is lower than that in the region Ra, is made thicker than the width Wa of each power supply line VDD (GL1) in the region Ra.

Thus, the rise in the wiring resistance of the power supply line VDD provided between the bump BMP (VDD) and the power supply switch circuit LPSW in the region Rb can be prevented, and the IR drop of the power supply voltage VDD can be reduced. As a result, even when the arrangement density Bb of the bumps BMP (VDD) in the region Rb is relatively low, the actual power supply capability to the virtual power supply line VVDD in the region Rb can be made greater than or equal to the actual power supply capability to the virtual power supply line VVDD in the region Ra.

### Fourth Embodiment

FIG. 10 is a planar view illustrating the outline of the layout of the standard cell block SCB in the fourth embodiment. Elements similar to those of the standard cell block SCB illustrated in FIG. 3 are denoted by the same symbols and detailed descriptions are omitted. The standard cell block SCB illustrated in FIG. 10 is provided in the internal circuit region INTR of the semiconductor device SEM as in FIG. 1, and has the same circuit configuration as in FIG. 2.

In the present embodiment, the arrangement densities Ba and Bb of the bumps BMP (VDD) are “0.5” and “0.2”, respectively, as in FIG. 3. Also, the arrangement density Db of the power supply lines VDD (GL1) and the ground lines VSS (GL1) provided in the region Rb is set higher than the arrangement density Da of the power supply lines VDD (GL1) and the ground lines VSS (GL1) provided in the region Ra.

That is, the arrangement pitch Db of the power supply lines VDD (GL1) and the ground lines VSS (GL1) provided in the region Rb is set lower than the arrangement pitch Da of the power supply line VDD (GL1) and the ground line VSS (GL1) provided in the region Ra.

For example, the number of power supply lines VDD (GL1) provided in the region Rb is four times the number of power supply lines VDD (GL1) provided in the region Rb in FIG. 3. The number of ground lines VSS (GL1) provided in the region Rb is twice the number of ground lines VSS (GL1) provided in the region Rb in FIG. 3. The power lines VDD (GL1) may be provided by being stacked in the semiconductor device SEM.

The number Pb of power switch circuits PSW arranged in the region Rb is equal to the number Pa of power switch circuits PSW arranged in the region Ra. The number Gb, Ga of gates GT in each switch transistor SWT in the regions Rb, Ra are equal to each other, and the number Fb, Fa of fins FIN in each switch transistor SWT in the regions Rb, Ra are equal to each other. Further, the widths Wa, Wb of the power supply lines VDD (GL1) provided in the regions Ra, Rb are equal to each other. Other configurations of the standard cell block SCB are the same as those in FIG. 3.

Also in the present embodiment, the condition that makes the actual power supply capability to the virtual power line VVDD in the region Rb equal to the actual power supply capability to the virtual power line VVDD in the region Ra can be determined by the above formula (1). Each element in formula (1) other than the arrangement densities Ba and Bb of the bumps BMP (VDD) and the arrangement pitches Da and Db of the power lines VDD (GL1) are the same on the left and right sides, and, therefore, formula (1) can be transformed into formula (5).

Ba×Da=Bb×Db (5)

In formula (5), “Da” indicates the power supply capability to the virtual power line VVDD by the circuit alone without considering the arrangement density of the bumps BMP (VDD) in the region Ra. In formula (5), “Db” indicates the power supply capability to the virtual power line VVDD by the circuit alone without considering the arrangement density of the bumps BMP (VDD) in the region Rb.

In formula (5), “Ba×Da” on the left side indicates the actual power supply capability to the virtual power line VVDD as expressed by the product of the arrangement density of the bumps BMP (VDD) and the power supply capability. In formula (5), “Bb×Db” on the right side indicates the actual power supply capability to the virtual power line VVDD. “Ba×Da” on the left side of formula (5) is an example of the first parameter. “Bb×Db” on the right side of formula (5) is an example of the second parameter.

In the present embodiment, by making the arrangement pitch Db of the power supply lines VDD (GL1) in the region Rb smaller than the arrangement pitch Da of the power supply lines VDD (GL1) in the region Ra, the actual power supply capability to the virtual power supply line VVDD can be made equal in the regions Rb and Ra. The threshold voltage of the p-channel transistor P of the power switch circuit PSW in the region Rb may be set lower than the threshold voltage of the p-channel transistor P of the power switch circuit PSW in the region Rb.

In one or more of the first to third embodiments (FIGS. 3, 8 and 9), the wiring pitch Db of the power supply lines VDD (GL1) provided in the region Rb may be smaller than the wiring pitch Da of the power supply lines VDD (GL1) provided in the region Ra. Further, when the regions Ra and Rb are arranged side by side in the Y direction, the wiring pitch of the power supply lines VDD (GL2) provided in the region Rb may be smaller than the wiring pitch of the power supply lines VDD (GL2) provided in the region Ra.

As described above, the same effect as the above described embodiment can be obtained in the present embodiment. For example, the wiring pitch Db of the power supply lines VDD (GL1) in the region Rb, where the arrangement density Bb of the bumps BMP (VDD) is lower than that in the region Ra, is made smaller than the wiring pitch Da of the power supply lines VDD (GL1) in the region Ra.

Thus, the rise in the wiring resistance of the power supply line VDD provided between the bump BMP (VDD) and the power supply switch circuit LPSW in the region Rb can be prevented, and the IR drop of the power supply voltage VDD can be reduced. As a result, even when the arrangement density Bb of the bumps BMP (VDD) in the region Rb is relatively low, the actual power supply capability to the virtual power supply line VVDD in the region Rb can be made greater than or equal to the actual power supply capability to the virtual power supply line VVDD in the region Ra.

### Fifth Embodiment

FIG. 11 is a planar view illustrating the outline of the layout of the standard cell block SCB in the fifth embodiment. Elements similar to those of the standard cell block SCB illustrated in FIG. 3 are denoted by the same symbols and detailed descriptions are omitted. The standard cell block SCB illustrated in FIG. 11 is provided in the internal circuit region INTR of the semiconductor device SEM as in FIG. 1, and the circuit block is the same as in FIG. 2.

In the present embodiment, the arrangement densities Ba and Bb of the bumps BMP (VDD) are “0.5” and “0.2”, respectively, as in FIG. 3. Also, the arrangement densities Db of the power supply lines VDD (GL1) and the ground lines VSS (GL1) provided in the region Rb are respectively set higher than the arrangement densities Da of the power supply lines VDD (GL1) and the ground lines VSS (GL1) provided in the region Ra.

With this, the number of the power supply lines VDD (GL1) provided in the region Rb can be relatively larger than the number of the power supply lines VDD (GL1) provided in the region Ra, and the wiring resistance can be reduced. For example, the number of the power supply lines VDD (GL1) provided in the region Rb is six times the number of the power supply lines VDD (GL1) provided in the region Rb in FIG. 3. The number of ground lines VSS (GL1) provided in the region Rb is equal to the number of ground lines VSS (GL1) provided in the region Rb in FIG. 3. The power lines VDD (GL1) may be provided by being stacked in the semiconductor device SEM.

The number Pb of the power switch circuits PSW arranged in the region Rb is equal to the number Pa of the power switch circuits PSW arranged in the region Ra. The numbers Gb, Ga of the gates GT in each switch transistor SWT in the regions Rb, Ra are equal to each other, and the numbers Fb, Fa of the fins FIN in each switch transistor SWT in the regions Rb, Ra are equal to each other. Further, the widths Wa, Wb of the power supply lines VDD (GL1) provided in the regions Ra, Rb are equal to each other. Other configurations of the standard cell block SCB are the same as those in FIG. 3.

In the present embodiment, by making the arrangement density Db of the power supply lines VDD (GL1) in the region Rb higher than the arrangement density Da of the power supply lines VDD (GL1) in the region Ra, the actual power supply capability to the virtual power supply line VVDD can be made equal in the regions Rb and Ra. The threshold voltage of the p-channel transistor P of the power switch circuit PSW in the region Rb may be set lower than the threshold voltage of the p-channel transistor P of the power switch circuit PSW in the region Rb.

In one or more of the first to third embodiments (FIGS. 3, 8 and 9), the arrangement density Db of the power supply lines VDD (GL1) provided in the region Rb may be higher than the arrangement density Da of the power supply lines VDD (GL1) provided in the region Ra. When the regions Ra and Rb are arranged side by side in the Y direction, the arrangement density of the power supply lines VDD (GL2) provided in the region Rb may be higher than the arrangement density of the power supply lines VDD (GL2) provided in the region Ra.

As described above, the same effect as the above described embodiment can be obtained in the present embodiment. For example, the arrangement density Db of the power supply lines VDD (GL1) in the region Rb, where the arrangement density Bb of the bumps BMP (VDD) is lower than that in the region Ra, is made higher than the wiring density Da of the power supply lines VDD (GL1) in the region Ra.

Thus, the rise in the wiring resistance of the power supply line VDD provided between the bump BMP (VDD) and the power supply switch circuit LPSW in the region Rb can be prevented, and the IR drop of the power supply voltage VDD can be reduced. As a result, even when the arrangement density Bb of the bumps BMP (VDD) in the region Rb is relatively low, the actual power supply capability to the virtual power supply line VVDD in the region Rb can be made greater than or equal to the actual power supply capability to the virtual power supply line VVDD in the region Ra.

According to the disclosed technique, it is possible to prevent a difference from arising in the power supply capability to the circuit supplying the power supply voltage in regions in which the arrangement densities of the power supply terminals are different from each other.

Although the present invention has been described above with reference to the embodiments, the present invention is not limited to the requirements described in the embodiments. These points can be changed without departing from the scope of the present invention, and can be appropriately determined according to the implementation to which the present invention is applied.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a illustrating of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A semiconductor device comprising:
a first power line;
a second power line;
a circuit region including
a first region in which a plurality of first power supply terminals connected to the first power line are arranged at a first density in a planar view, and
a second region in which a plurality of second power supply terminals connected to the first power line are arranged at a second density that is lower than the first density in a planar view;
a plurality of first power switch circuits arranged in the first region and connecting the first power line to the second power line; and
a plurality of second power switch circuits arranged in the second region and connecting the first power line to the second power line, wherein
a second power supply capability to the second power line by a circuit including the first power line and the second power switch circuits is higher than a first power supply capability to the second power line by a circuit including the first power line and the first power switch circuits.

2. The semiconductor device according to claim 1, wherein
each of the plurality of the first power switch circuits includes a first transistor connecting the first power line to the second power line,
each of the plurality of the second power switch circuits includes a second transistor connecting the first power line to the second power line, and
a size of the second transistor is larger than a size of the first transistor.

3. The semiconductor device according to claim 1, wherein
each of the plurality of the first power switch circuits and each of the plurality of the second power switch circuits have a same circuit configuration with each other, and
an arrangement density of the plurality of the second power switch circuits is higher than an arrangement density of the plurality of the first power switch circuits.

4. The semiconductor device according to claim 1, wherein a width of the first power line provided in the second region is thicker than a width of the first power line provided in the first region.

5. The semiconductor device according to claim 1, wherein an arrangement density of the first power lines provided in the second region is higher than an arrangement density of the first power lines provided in the first region.

6. The semiconductor device according to claim 5, wherein an arrangement pitch of the first power lines provided in the second region is smaller than an arrangement pitch of the first power lines provided in the first region.

7. The semiconductor device according to claim 5, wherein a number of the first power lines provided in the second region is larger than a number of the first power lines provided in the first region.

8. The semiconductor device according to claim 1, wherein a first parameter expressed by a product of an arrangement density of the plurality of the first power supply terminals in the first region and the first power supply capability, is equal to a second parameter expressed by a product of an arrangement density of the plurality of the second power supply terminals in the second region and the second power supply capability.
